(19) United States
(12) Patent Application Publication
(10) Pub. No.: US 2015/0270004 A1
(43) Pub. Date: Sep. 24, 2015

(54) Method for Performing Erase Operation in Non-Volatile Memory

(71) Applicant: Elite Semiconductor Memory Technology Inc., Hsinchu (TW)

(72) Inventor: Cheng-Hung TSAI, New Taipei City (TW)

(73) Assignee: Elite Semiconductor Memory Technology Inc., Hsinchu (TW)

(21) Appl. No.: 14/221,079

(22) Filed: Mar. 20, 2014

(51) Int. Cl. G11C 16/16; G11C 16/34

(52) U.S. Cl. CPC G11C 16/16; G11C 16/3445; G11C 16/3409

(57) ABSTRACT

A method for performing an erase operation in a non-volatile memory incorporates the steps of selecting a block on which to perform an erase operation; erasing the selected block using a plurality of erase pulses; receiving erase data of the selected block; determining an over-erase correction verify voltage level based on the erase data; and over-erase correcting the selected block until each cell within the selected block passes the over-erase correction verify voltage level.

### BACKGROUND OF THE INVENTION

1. Field of the Invention

The present invention relates to a method for performing an erase operation in a nonvolatile memory.

2. Description of the Related Art

Semiconductor memory devices are devices in which data can be stored and from which stored data can be retrieved. Semiconductor memory devices can be classified into volatile memory and nonvolatile memory. The volatile memory needs a power supply to retain data while the nonvolatile memory can retain data even when power is removed. Therefore, the nonvolatile memory devices have been widely used in applications in which power can be interrupted suddenly.

The nonvolatile memory devices comprise electrically erasable and programmable ROM cells, known as flash EEPROM cells. FIG. 1 shows a vertical cross-section of the flash EEPROM cell 10. Referring to FIG. 1, a deep n-type well 12 is formed in a bulk region or a P-type substrate 11, and a p-type well 13 is formed in the n-type well 12. An N-type source region 14 and an N-type drain region 15 are formed in the P-type well 13. A p-type channel region is formed between the source region 14 and the drain region 15. A floating gate 17, which is insulated by an insulating layer 16, is formed on the P-type channel region. A control gate 19, which is insulated by another insulating layer 18, is formed above the floating gate 17.

FIG. 2 shows a simplified flowchart diagram of an erase operation performed on a flash memory including a plurality of flash cells 10. Referring to FIG. 2, the erase operation includes three separate procedures, including a preprogram procedure 22, an erase procedure 24, and an over erase correction (OEC) procedure 26. FIG. 3A shows threshold voltage (Vt) distributions of the flash cells 10 within a block during the erase operation of FIG. 2. The X-axis corresponds to the threshold voltage of memory cells and the Y-axis represents the number of memory cells. The erase operation is described with reference to both the flowchart diagram of FIG. 2 and the threshold voltage distributions of FIG. 3A.

At first step 222, a preprogram verify test is performed for a selected memory block. During the preprogram verify test, the Vt of one or more flash cells is compared with a preprogram verify threshold (PVT) voltage level. If Vt is below the PVT voltage level, the flow proceeds to step 224 to perform a preprogram procedure of one or more memory cells which have failed the preprogram verify test, in which a preprogram pulse of a selected voltage level is applied to the flash cells to increase Vt. After the step 224, the flow returns to step 222 to determine whether the Vt of the flash cells is above the PVT voltage level. Referring to FIG. 2, the steps 222 and 224 are repeated until the Vt of each flash cell of the selected memory block is above the PVT voltage.

After the preprogram procedure 22 is completed, the flow proceeds to step 242 of the erase procedure 24 in which an erase verify test is performed for the flash cells within the memory block to determine whether all of the cells are erased. During the erase verify test, the Vt of each of the memory cells is compared with an erase verify threshold (EVT) voltage level. If the Vt of any flash cell of the memory block is above the EVT voltage level, the flow proceeds to step 244 to perform the erase procedure 26 of the entire memory block, in which one or more erase pulses of high voltage levels are applied to the memory block to decrease Vt of the flash cells within the memory block. After the step 244, the flow returns to step 242 to determine whether the Vt of each flash cell of the memory block is below the EVT voltage level or not. Referring to FIG. 2, the steps 242 and 244 are repeated by applying additional erase pulses until the Vt of each flash cell within the selected memory block is below the EVT voltage level.

During the erase procedure 24, if a single flash cell fails the erase verify test, the entire memory block receives another erase pulse until the Vt of every memory cell is below the EVT voltage level. In this manner, many of the flash cells are “over erased” during the erase procedure. The over erased cells have low erased threshold voltages, which may result in bit-line leakage current during reading of the cells, thereby causing false readings and weak program capability. Therefore, the over-erase correction procedure 26 is required to adopt to correct the Vt of the over erased cells.

Referring to FIG. 2, after the erase procedure 24 is completed, the flow proceeds to step 262 of the over erase correction procedure 26 in which an over-erase verify test is performed for the selected memory block. At step 262, the Vt of each of the flash cells is compared with a over-erase correction verify threshold (OECVT) voltage level. If Vt of any flash cell of the memory block is below the OECVT voltage level, the flow proceeds to the step 264 to perform the OEC procedure 26 of the entire memory block, in which one or more over-erase correction pulses of intermediate voltage levels are applied to the memory block to increase Vt of the flash cells of the memory block. After the step 264, the flow returns to step 262 to determine whether the Vt of any one of the memory cells is above the OECVT voltage level. Referring to FIG. 2, the steps 262 and 264 are repeated by applying additional over-erase correction pulses until the Vt of each flash cell of the selected memory block is above the OECVT voltage level as shown in FIG. 3A.

Referring to FIG. 3A, the OEC procedure increases (or corrects) the low threshold voltages of the identified flash cells to effectively narrow the Vt distributions of the erased cells. However, with the increasing program and erase cycles of the flash cells, the gm degradation of the flash cell is growing worse. It may cause some flash cells to fall outside the original set range between the OECVT voltage level and the EVT voltage level as shown in FIG. 3B. In addition, the number of the cells having the low erased threshold voltages close to the OECVT voltage level is increased after a high number of cycles, which may result in high bit-line leakage current and weak program capability. Therefore, there is a need to provide a flash memory device having an adjustable Vt distribution after a high number of the erase cycles.

### SUMMARY OF THE INVENTION

One aspect of the present invention is to provide a method for performing an erase operation in a non-volatile memory. According to one embodiment of the present invention, the method comprises selecting a block on which to perform an erase operation; erasing the selected block using a plurality of erase pulses; receiving erase data of the selected block; determining an over-erase correction verify voltage level based on the erase data; and over-erase correcting the selected block until each cell within the selected block passes the over-erase correction verify voltage level.

### BRIEF DESCRIPTION OF THE DRAWINGS

The invention will be described according to the appended drawings in which:

FIG. 1 shows a vertical cross-section of the flash EEPROM cell;

FIG. 2 shows a simplified flowchart diagram of an erase operation performed on a flash memory including a plurality of flash cells;

FIGS. 3A and 3B show Vt distributions of the flash cells within a block during the erase operation of FIG. 2;

FIG. 4 shows a block diagram of a nonvolatile semiconductor memory device 40 according to one embodiment of the present invention;

FIG. 5 shows a flowchart diagram illustrating a method of performing an erase operation on the memory device according to one embodiment of the present invention;

FIG. 6 is a timing diagram showing the erase procedure performed for the memory block according to one embodiment of the present invention;

FIG. 7A shows Vt distributions of the flash cells within a block after the erase operation according to one embodiment of the present invention;

FIG. 7B shows Vt distributions of the flash cells within a block after the erase operation according to another embodiment of the present invention;

FIG. 8 is a timing diagram showing the erase procedure performed for the memory block according to another embodiment of the present invention;

FIG. 9A shows bias voltages applied to the memory block according to one embodiment of the present invention; and

FIG. 9B shows bias voltages applied to the memory block according to another embodiment of the present invention.

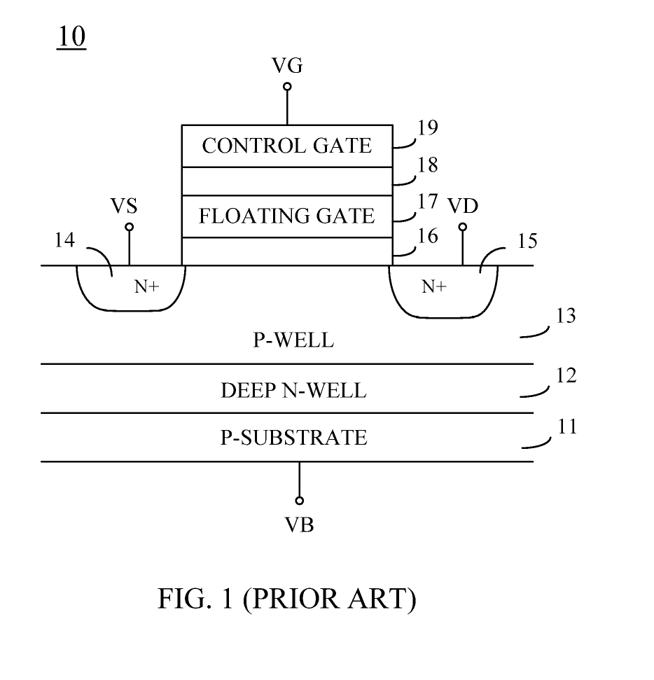

### DETAILED DESCRIPTION OF THE INVENTION

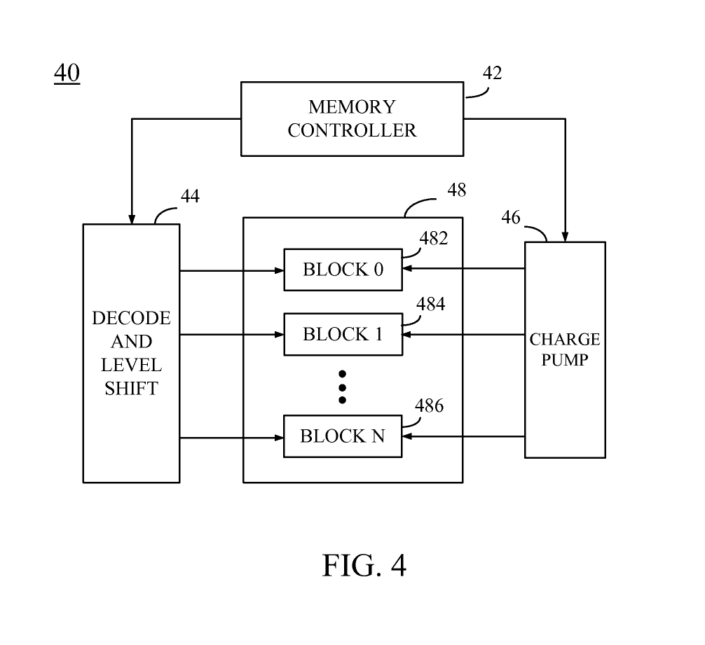

In order to explain the method of performing an erase operation in a nonvolatile memory of the present invention, the nonvolatile semiconductor memory device that performs the method of the present invention will be described herein. FIG. 4 shows a block diagram of a nonvolatile semiconductor memory device 40 according to one embodiment of the present invention. Referring to FIG. 4, the memory device 40 comprises a memory controller 42, a decode and level shift circuit 44, a charge pump 46, and a memory array 48 comprising a plurality of memory blocks 482, 484, and 486. Each of the memory blocks comprises a plurality of memory cells (not shown) arranged in the form of a matrix. The memory cells are connected to word lines (not shown) in rows and to bit lines (not shown) in columns.

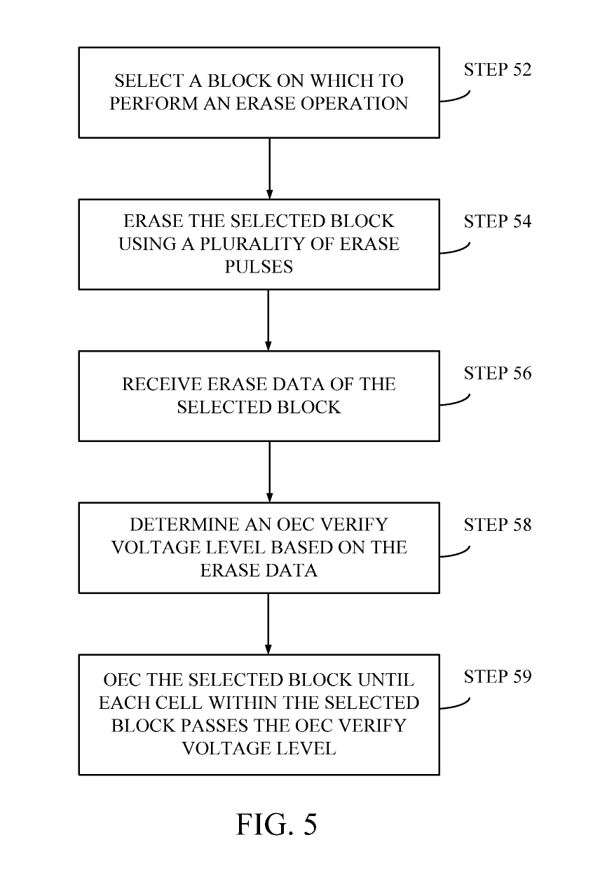

FIG. 5 shows a flowchart diagram illustrating a method of performing an erase operation on the memory device 40 according to one embodiment of the present invention. The method may be briefly summarized as follows:

Step 52: Select a block on which to perform an erase operation;

Step 54: Erase the selected block using a plurality of erase pulses; Step 56: Receive erase data of the selected block;

Step 58: Determine an over-erase correction (OEC) verify voltage level based on the erase data; and

Step 59: Over-erase correct the selected block until each cell within the selected block passes the over-erase correction verify voltage level.

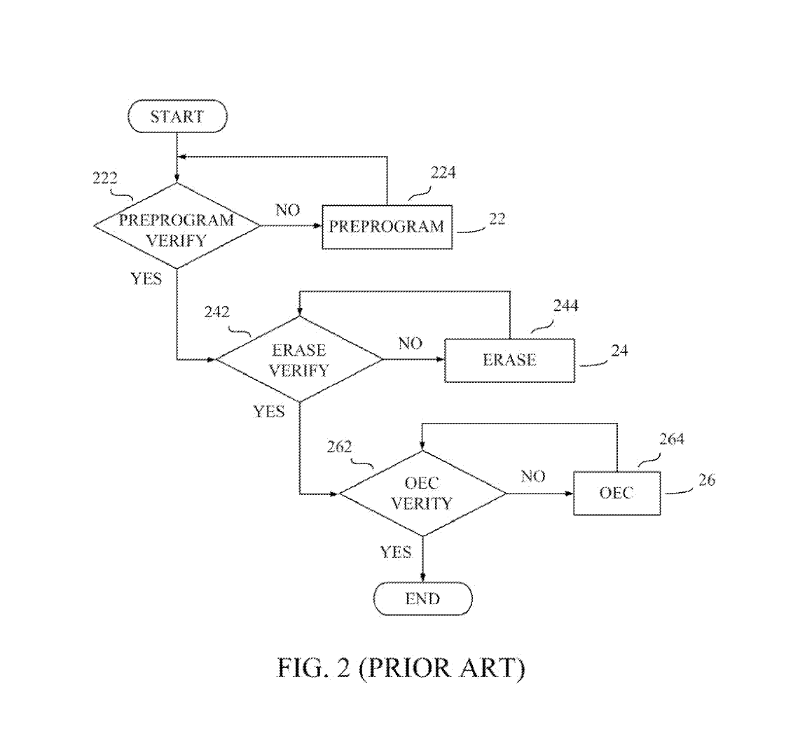

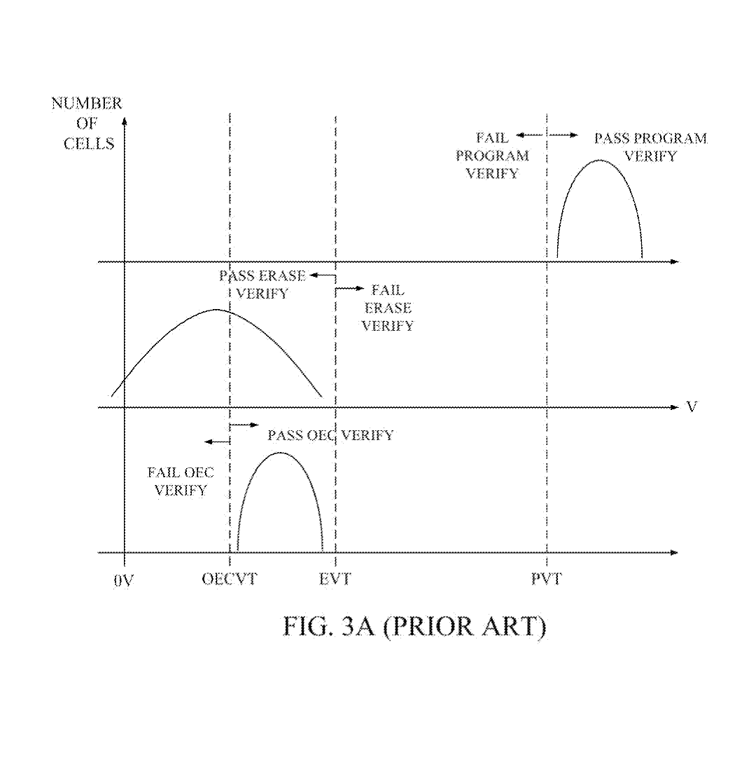

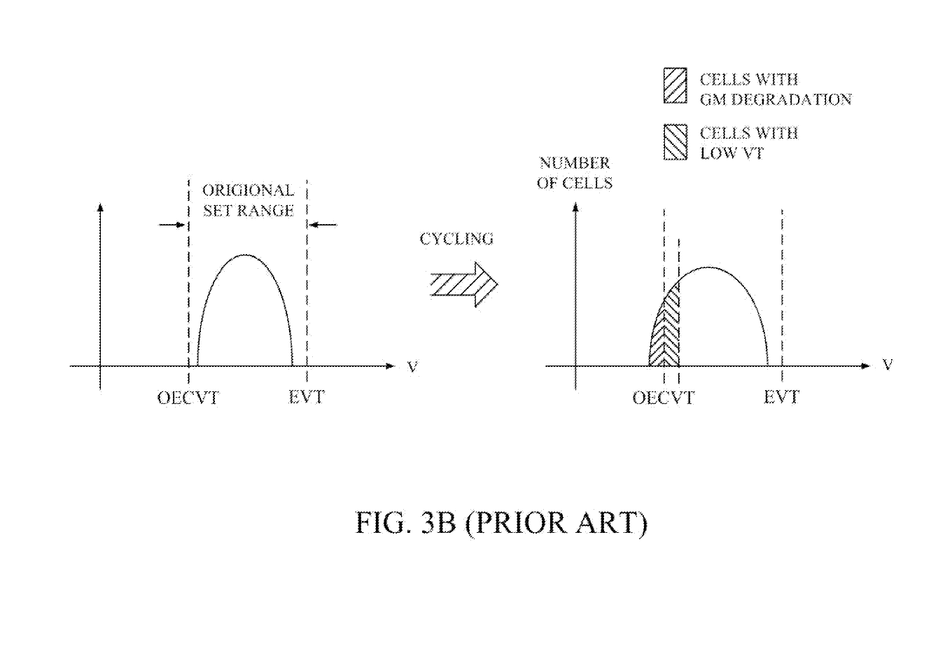

The details of the flow for performing the erase operation of the present invention will be described below with respect to FIG. 4 and FIG. 5. Referring to FIG. 4, the decode and level shift circuit 44 receives a plurality of address signals from the memory controller 42. The address signals comprise row address signals, column address signals, and block select signals. In this embodiment, the decode and level shift circuit 44 receives a block select signal from the controller 42 and then selects the memory block 482 to perform an erase operation at the first time. Thereafter, a preprogram procedure, an erase procedure, and a self-adjusting over-erase correction (OEC) procedure are performed for the selected memory block 482 in sequence. Since the preprogram procedure of the erase operation is the same as or similar to the preprogram procedure 22 of the erase operation of FIG. 2, the detailed descriptions thereof will be omitted.

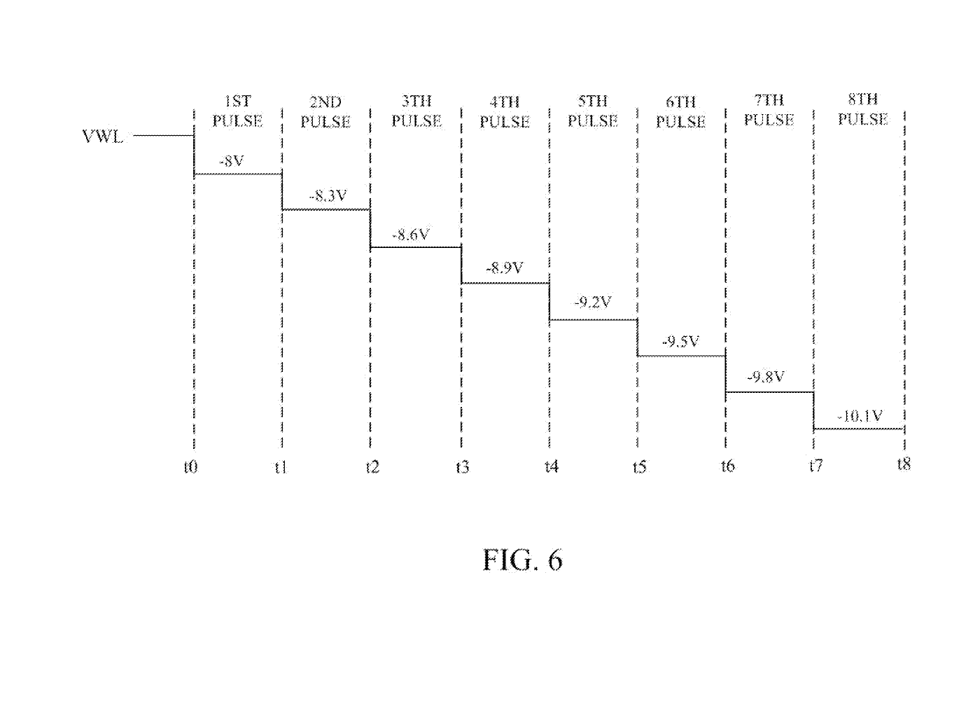

Referring to FIG. 5, after the memory block is selected and the preprogram procedure of the selected block is completed, the flow proceeds to step 54 in which a plurality of erase pulses of high voltage levels from the charge pump 46 of FIG. 4 are applied to the selected block 482 until the memory cells within the selected block 482 pass an erase verify threshold (EVT) voltage level. That is, the Vt of each flash cell of the memory block 482 is below the EVT voltage level after the erase procedure is completed. If the Vt of any flash cell of the memory block is above the EVT voltage level during the erase procedure, additional erase pulses of high voltage levels are applied to the memory block 482 to decrease Vt of the cells. FIG. 6 is a timing diagram showing the erase procedure performed for the memory block 482 according to one embodiment of the present invention. Referring to FIG. 6, the successive erase pulses are applied to the memory cells of the memory block 482 between the time t0 and the time t8. The erase pulses applied ramp down in voltage from about −8V to about −10.1V. In this embodiment, the amplitude of each successive pulse is increased by a constant value, i.e., 300 mV. Therefore, after the time t7, the amplitude of the pulse reaches −10.1V, which is close to the junction breakdown voltage of the flash cell. After the time t8, the erase procedure for the memory block 482 ends because the amplitude of the next pulse may cause damage to the flash cell. It is noted that the amplitude of each successive pulse can be increased by a variable.

After the erase procedure is completed, a self-adjusting OEC procedure is performed to increase Vt of the cells within the memory block 482. Before applying the OEC pulse to the block 482, the memory controller 42 determines a current OEC verify voltage level based on the erase data of the block 482. In one embodiment of the present invention, the memory controller 42 may determine the OEC verify voltage level based on the number of the real erase pulse applied to the block 482. The memory block 482 may only require a few of pulses (e.g., two or three successive erase pulses) to correct the Vt of the cells. In this condition, a lower OEC verify voltage level is required and a wide Vt distribution of the erased cells is obtained. However, with the increasing program and erase cycles of the flash cells, much more erase pulses are required to correct the Vt of the cells. In this condition, a higher OEC verify voltage level is required to narrow the Vt distribution of the cells.

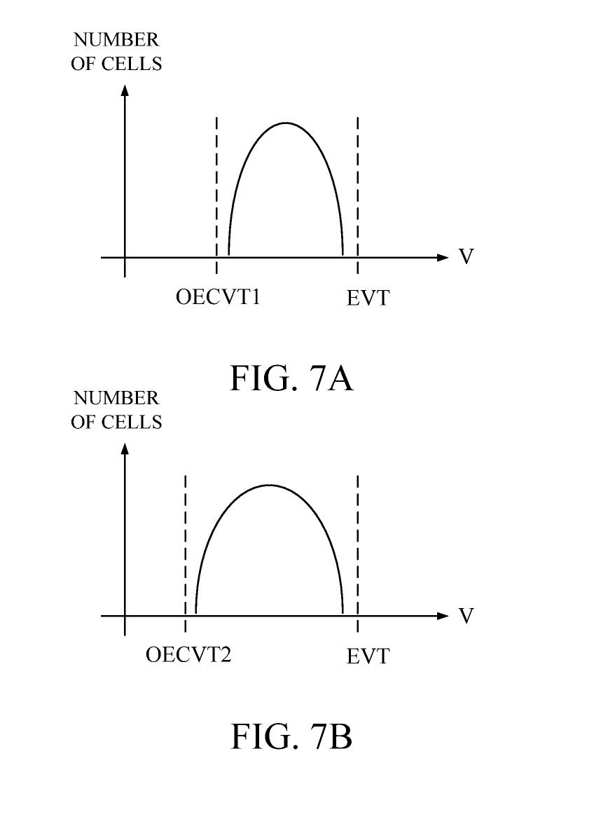

In order to determine the OEC verify voltage level, a counter (not shown) of the memory device 40 counts the number of the erase pulses applied to the block 482, and the controller 42 determines whether the number of the erase pulses is greater than a preset value PSET or not. In this embodiment, the preset value PSET is set to six. Therefore, if the number of real erase pulses applied to the block 482 is equal to or greater than six, the OEC verify test is performed using a higher OEC verify voltage level OECVT1 as shown in FIG. 7A. Otherwise, if the number of real erase pulses applied to the block 482 is less than six, the OEC verify test is performed using a lower OEC verify voltage level OECVT2 as shown in FIG. 7B.

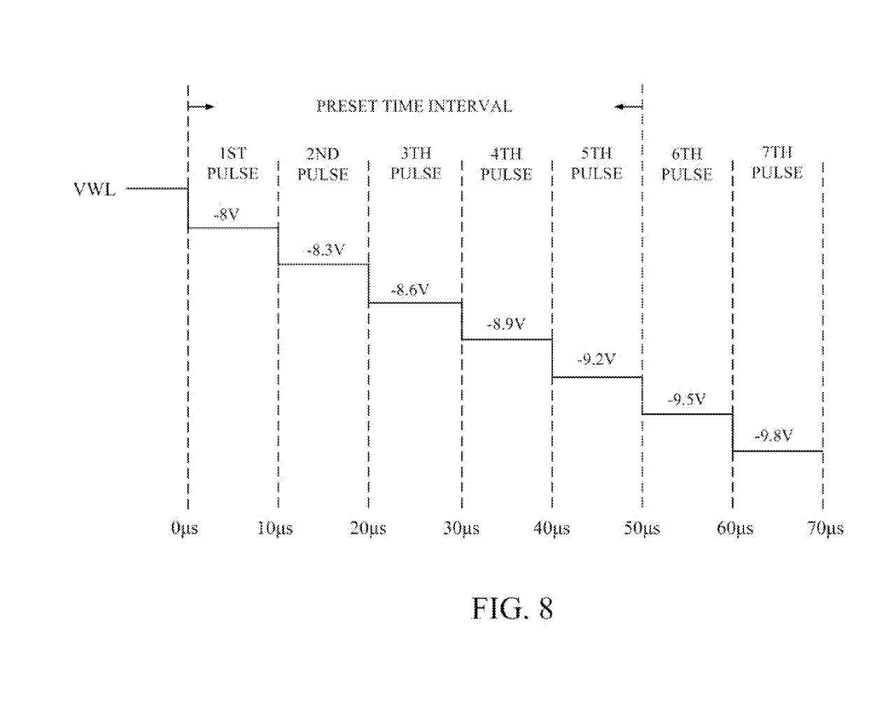

In another embodiment of the present invention, the memory controller 42 may determine the OEC verify voltage level based on the total time interval of the erase pulses applied to the block 482. Referring to FIG. 8, each of the erase pulses has a period of 10 μS, and the last erase pulse applied to the block is the seventh erase pulse. Since the total time interval of the erase pulses applied to the block 482 in this embodiment is greater than a preset time interval TSET (50 μS in this case), an OEC verify test is performed using a higher OEC verify voltage level OECVT1 as shown in FIG. 7A. Otherwise, if the total time interval of the erase pulses applied to the block 482 is less than 50 μS, the OEC verify test is performed using a lower OEC verify voltage level OECVT2 as shown in FIG. 7B.

In the above embodiments, the memory controller 42 determines the OEC verify voltage level based on the number of the erase pulses or based on the total time interval of the erase pulses applied to the block 482. However, the disclosure is not limited to these embodiments. According to yet another embodiment of the present invention, the memory controller 42 can determine the OEC verify voltage level based on the word line voltage applied to the flash cells within the block. For example, a voltage comparator may be used to compare the voltage VWL applied to the word line of the flash cells with a preset voltage VSET, i.e., −9.3V. Therefore, if the voltage VWL of the last erase pulse is equal to or greater than −9.3V, an OEC verify test is performed using a higher OEC verify voltage level OECVT1 as shown in FIG. 7A. Otherwise, if the voltage applied to the word line of the flash cell applied to the block 482 is less than −9.3V, an OEC verify test is performed using a lower OEC verify voltage level OECVT2 as shown in FIG. 7B.

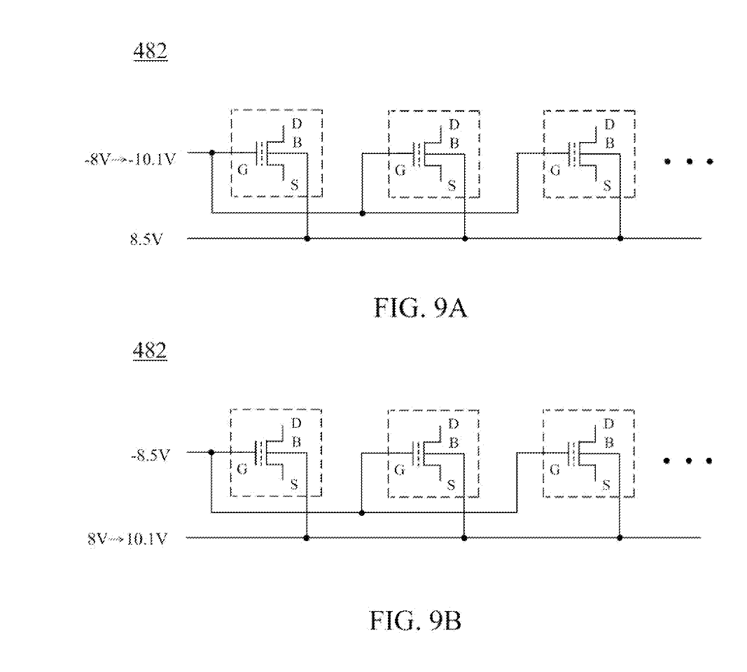

In the above embodiments, each flash cell within the memory block 482 has a gate (G) terminal, a drain (D) terminal, a source (S) terminal and a body (B) terminal as shown in FIG. 9A. The gate terminal of each flash cell receives a plurality of erase pulses having increasing amplitude until the erase procedure is completed. Meanwhile, the body terminal, which is sometimes referred to as a well terminal, of each flash cell is biased at a fixed voltage, i.e., 8.5V. However, the present invention is not limited to such a bias manner. Referring to another embodiment as shown in FIG. 9B, during the erase procedure, the gate terminal of each flash cell can be biased at a fixed voltage, i.e., −7V, and the body terminal of each flash cell can receive a plurality of erase pulses having increasing amplitude between 8V and 10.1V. In addition, the amplitude of each successive pulse can increased by a constant value or increased by a variable.

After the OEC verify voltage level is selected, the OEC pulse is applied to one or more of the memory cells whose threshold voltages are below the OEC verify voltage level. The OEC pulse has a selected voltage level to increase Vt of the cells of the memory block. After the OEC procedure, the Vt of each memory cell of the memory block 482 is between an erase verify threshold voltage level and the OEC verify voltage level as shown in FIG. 7A and FIG. 7B. Since the OEC verify voltage can be adjustable based on the erase data of the selected block, the memory device can achieve better performance in data reading and program capability.

The above-described embodiments of the present invention are intended to be illustrative only. Numerous alternative embodiments may be devised by those skilled in the art without departing from the scope of the following claims.

What is claimed is:

1. A method for performing an erase operation in a non-volatile memory:
selecting a block on which to perform an erase operation;
erasing the selected block using a plurality of erase pulses;
receiving erase data of the selected block;
determining an over-erase correction verify voltage level based on the erase data; and
over-erase correcting the selected block until each cell within the selected block passes the over-erase correction verify voltage level.

2. The method of claim 1, wherein the erasing the selected block using the plurality of erase pulses comprises:
performing an erase verify test for the selected block after applying each erase pulse to the selected block; and
stopping applying the plurality of erase pulses to the selected block if each cell within the selected block passes the erase verify test.

3. The method of claim 1, wherein the plurality of erase pulses have increasing amplitude and the amplitude of each successive pulse is increased by a constant value.

4. The method of claim 1, wherein the plurality of erase pulses have increasing amplitude and the amplitude of each successive pulse is increased by a variable.

5. The method of claim 1, wherein the plurality of erase pulses are applied to gate terminals of memory cells within the selected block.

6. The method of claim 1, wherein the plurality of erase pulses are applied to well terminals of memory cells within the selected block.

7. The method of claim 1, wherein the erase data comprises the number of the erase pulses applied to the selected block, and the over-erase correction verify voltage level is determined based on the number of the erase pulses.

8. The method of claim 7, wherein the determining the over-erase correction verify voltage level based on the erase data comprises:
counting the number of the erase pulses applied to the selected block;
if the number of the erase pulses is greater than a preset value, applying a first over-erase correction verify voltage level to the selected block; and
if the number of the erase pulses is less than the preset value, applying a second over-erase correction verify voltage level to the selected block,
wherein the first over-erase correction verify voltage level is higher than the second over-erase correction verify voltage level.

9. The method of claim 1, wherein each of the plurality of erase pulses has a corresponding time interval, and the erase data comprises the total time interval of the erase pulses applied to the selected block.

10. The method of claim 9, wherein the determining the over-erase correction verify voltage level based on the erase data comprises:
calculating the total time interval of the erase pulses applied to the selected block;
if the total time interval is greater than a preset value, applying a first over-erase correction verify voltage level to the selected block; and
if the total time interval is less than the preset value, applying a second over-erase correction verify voltage level to the selected block,
wherein the first over-erase correction verify voltage level is higher than the second over-erase correction verify voltage level.

11. The method of claim 1, wherein the plurality of erase pulses have increasing amplitude, and the erase data comprises the amplitude of the last erase pulse applied to the selected block.

12. The method of claim 11, wherein the determining the over-erase correction verify voltage level based on the erase data comprises:
comparing the amplitude of the last erase pulse applied to the selected block with a preset value;
if the amplitude of the last erase pulse is greater than a preset value, applying a first over-erase correction verify voltage level to the selected block; and
if the amplitude of the last erase pulse is less than the preset value, applying a second over-erase correction verify voltage level to the selected block,
wherein the first over-erase correction verify voltage level is higher than the second over-erase correction verify voltage level.
